(19) United States
(12) Patent Application Publication
(10) Pub. No.: US 2006/0091524 A1
(43) Pub. Date: May 4, 2006

(54) Semiconductor module, process for producing the same, and film interposer

(76) Inventors: Seiji Karashima, Hirakata-shi (JP); Yoshihisa Yamashita, Kyoto-shi (JP); Seiichi Nakatani, Hirakata-shi (JP); Toshiyuki Kojima, Uji-shi (JP); Shingo Komatsu, Katano-shi (JP); Satoru Tomekawa, Yokohama-shi (JP)

Correspondence Address: WENDEROTH, LIND & PONACK L.L.P., 2033 K. STREET, NW, SUITE 800, WASHINGTON, DC, 20006, US

(21) Appl. No.: 11/262,758

(22) Filed: Nov. 1, 2005

(30) Foreign Application Priority Data
Nov. 2, 2004 (JP) P2004-318891

(51) Int. Cl. H01L 23/12

(52) U.S. Cl. 257/700

(57) ABSTRACT

A semiconductor module, comprising: a semiconductor element having a principal face on which an element electrode is formed; and a film member comprising an insulating resin layer having a front face and a rear face which is opposite to said front face, and a wiring pattern formed on the rear face of said layer, wherein said semiconductor element is superposed on said film member so that the principal face of said semiconductor element is in contact with the front face of the insulating resin layer of said film member; and a part of the wiring pattern of said film member extends through said insulating resin layer, so that said part is in contact with the element electrode of said semiconductor element.

### CROSS REFERENCE TO RELATED PATENT APPLICATION

The present application claims the right of priority of Japanese Patent Application No.2004-318891 (filed Nov. 2, 2004, the title of the invention: “SEMICONDUCTOR MODULE, PROCESS FOR PRODUCING THE SAME, AND FILM INTERPOSER”), the disclosure of which is incorporated herein by reference in its entirety.

### FIELD OF THE INVENTION

The present invention relates to a semiconductor module, and a process for producing the same. In particular, the present invention relates to the semiconductor module wherein a semiconductor element is superposed on a film member. Furthermore, the present invention relates to a film interposer.

### BACKGROUND OF THE INVENTION

In recent years, not only is an electronics device becoming smaller, but also such device is increasingly becoming sophisticated. This results in a high pin-count of a semiconductor composing the electronics device as well as a miniaturization of various components. Not only the number of wirings used for a printed board having the semiconductor element mounted thereon, but also a density of the printed board increases dramatically. Above all, the number of lead wires or leads extended from the semiconductor element (e.g. semiconductor chip) as well as the terminal number is increasing markedly. Therefore, a fine-pitch connection technique has become much more important in these days of an ongoing miniaturization of the printed board (i.e. wiring board).

At present, there are three main types of the fine-pitch connection technique: (i) wire bonding technique (WB); (ii) flip chip bonding technique (FC); and (iii) tape automated bonding technique (TAB). Each of them will be concisely described in the following paragraphs.

To begin with, the wire bonding technique will be described. Japanese Patent Kokai Publication No.4-286134, for example, discloses the wire bonding technique. In this technique, a gold wire (20 to 25 μm in diameter) is used to connect between an electrode of a semiconductor chip and an electrode of a lead frame. A connection between each electrode and the gold wire is achieved due to a so-called solid phase diffusion caused by a heat treatment or an ultrasonic wave treatment.

With reference to FIGS. 19(a) and (b), the wire bonding technique disclosed in Japanese Patent Kokai Publication No.4-286134 will be hereinafter described. FIG. 19(a) shows a top view of an embodiment obtained by the wire bonding technique, and also FIG. 19(b) shows a cross-sectional view of the embodiment taken along the line A-A indicated in FIG. 19(a).

In a process of this technique, first, a die bonding of a semiconductor chip 501 and a part of a lead frame 504 (i.e. die pad) is carried out, followed by carrying out a wire bonding between wire bonding pads 502 of the semiconductor 501 and external terminals 505 of the lead frame 504 (i.e. inner lead parts) by means of boding wires 503. Subsequently, the area including the semiconductor chip 501 and inner leads of the external terminals 505 is sealed within a sealing resin 506. As a result, a resin sealing body (i.e. semiconductor module) 500 as shown in FIG. 20 for example is obtained. A region of external terminals 505 outside the sealing resin 506 is connected to a wiring board (not shown) so that the semiconductor chip 501 and the wiring board are electrically interconnected.

There are, however, a few problems associated with the wire bonding technique. One of them is the fact that a packaging or mounting area of the semiconductor element (i.e. the module 500 including the semiconductor chip 501 as shown in FIG. 20) becomes larger. That is to say, the semiconductor chip 501 is connected to the external terminals 505 via the bonding wires 503, not directly connected to the wiring board. Thus, the size of the resulting semiconductor module 500 inevitably becomes larger than that of the semiconductor chip 501, which leads to a larger packaging area of the semiconductor module 500.

Another problem is related to a troublesome connection operation. In this technique, the wire bonding pads 502 of the semiconductor chip 501 are connected to the external terminals 505 by means of the bonding wire one by one. Thus, the more the terminals are provided, the more troublesome the connection operation becomes. Further another problem is related to the fact that, as shown in FIG. 19(b), the bonding wires 503 are respectively connected to the external terminals 505 so that the wires 503 extend above the upper surface level of the semiconductor chip 501, and thereafter the sealing operation is carried out by means of the sealing resin 506 as shown in FIG. 20. Thus, there is a limitation on thinness of the semiconductor element 500. In addition to that, the pitch of the semiconductor element 500 is substantially defined or formed by the pitch of the external terminals 505 arranged on the lead frame 504, and therefore there is a limitation on fineness of the pitch.

In the second place, the flip chip bonding technique will be hereinafter described. Japanese Patent Kokai Publication No.2000-36504, for example, discloses (i.e. projecting electrode) is formed on the semiconductor chip, followed by connecting the bump to an electrode of a wiring board. The technique is characterized in that an electrode-forming surface of the semiconductor chip and an electrode-forming surface of the wiring board are facing each other.

With reference to FIG. 21, the flip chip bonding technique disclosed in Japanese Patent Kokai Publication No.2000-36504 will be hereinafter described. FIG. 21 shows a cross-sectional view of a semiconductor device 600 obtained according to the flip chip bonding technique.

In a process of this technique, each of electrodes 604 of the semiconductor chip 605 is electrically connected to each of wiring patterns 602 of the board 601 via a bump 603. In other words, through the intervention of bumps 603, electrodes 604 of the semiconductor chip 605 having a sensitive area provided with a transistor are connected to predetermined wiring patterns 602 formed on the board 601. As a result, a clearance gap between the board 601 and the semiconductor 605 is formed. Subsequently, a resin material is poured into the clearance gap to form the sealing resin body 607. This causes the wiring pattern 602, the bump 603 and the electrode 604 to be embedded in the resin material. As a result, the semiconductor device 600 having a configuration as shown in FIG. 21 is obtained.

There are, however, a few problems associated with the flip chip bonding technique. One of them is the fact that an alignment of the semiconductor chip 605 with respect to the board 601 is hard to perform. The reason for this is that the bump 603 cannot be seen directly from the outside since the semiconductor chip 605 is superposed on the substrate 601 in such a manner that the electrode-forming surface of the semiconductor chip 605 faces downward. Another reason for the difficult alignment is that a pitch of the electrodes 604 of the semiconductor chip 605 for the case of the flip chip bonding technique is finer than the pitch of the external terminals for the case of the wire bonding technique.

Another problem is the fact the board 601 is liable to be expensive in the case of flip chip bonding technique. The reason for this is that the board 601 requires a fine wiring patterns 602 corresponding to the pitch of the electrodes 604 of the semiconductor chip 605. Another reason is that some boards 601 need to be stacked on each other to form a multilayer board in the case where a lot of input-output terminals are provided. Further another problem associated with the flip chip bonding technique is the fact that a coefficient of linear expansion of the semiconductor chip 605 needs to be matched with that of the board 601 as far as possible. Otherwise an undesired stress occurs in the bump 603. However, such matching is troublesome, which increases the production cost of the board 601.

Further another problem associated with the flip chip bonding technique is the fact that an additional operation steps and an additional cost related thereto are brought about. That is to say, the semiconductor chip 605 and the board 601 need to be interconnected through the intervention the bumps 603, followed by pouring the resin material (underfill agent) 607 into the clearance gap formed between the semiconductor chip 605 and the board 601, which in itself leads to increase in the number of operation steps as well as the production cost. Further another problem is the fact that the semiconductor chip 605 is less likely to adequately release heat therefrom due to an existence of the bumps 603 located between the semiconductor chip 605 and the board 601. The semiconductor chip 605 is connected to the board 601 in a point-contact mode, not in a plane-contact mode for the case of the wire bonding technique. This is why the heat is not effectively released in the case of the flip chip bonding technique. Further another problem associated with the flip chip bonding technique is the fact that the formation of the bump 600 in itself is hard to perform.

In the third place, the TAB technique will be hereinafter described. Japanese Patent Kokai Publication No.8-88245, for example, discloses the TAB technique. In this technique, the semiconductor chip is connected to an elongated tape having lead wirings thereon, and subsequently the resulting semiconductor provided with the lead wirings is punched out from the elongated tape to form a connection between the lead wiring and a board. Basically, these steps of the TAB technique are automatically carried out by means of a so-called reel-to-reel process.

With reference to FIGS. 22 and 23, the TAB technique disclosed in Japanese Patent Kokai Publication No.8-88245 will be hereinafter described. FIG. 22 shows a cross-sectional view of a semiconductor device 700 obtained by means of the TAB technique. FIG. 23 shows a view of the embodiment wherein the semiconductor device 700 is mounted on the substrate 709.

The semiconductor device shown in FIG. 22 is composed of a base film 702 of a film carrier tape and a semiconductor IC chip 701 disposed in a “device hole” 702b of the base film 702. A copper foil wiring 703 is formed on the base film 702, and also an electrode 701a of the semiconductor IC chip 701 is connected to an inner lead 703a provided at the inner edge of the copper foil wiring 703. A land 703b for an external connection is provided at the external side of the inner lead 703a, and also a solder bump 706 is formed on the land 703b. A through-hole 702a is provided in the base film 702, and also an aperture 703c is provided in the center of the land 703b. A cover resist 704 is formed on the film carrier tape except for the region of the land 703b. A sealing resin 705 for protecting the semiconductor IC chip 701 is provided in the device hole 702b.

In the shown semiconductor device 700, a solder bump 706 acts as an outer lead. Therefore, as shown in FIG. 23, the solder bumps 706 are connected to pads 709a provided on a mounting board 709. In this case, the semiconductor device 700 is mounted on the board 709 by means of a batch reflow process.

There are, however, a few problems associated with the TAB technique. One of them is the fact that the TAB technique is troublesome to perform since an inner lead bonding (ILB) step is carried out independently of an outer lead bonding (OLB) step. Such two steps are essential for the TAB technique, one of which is a step for connecting the inner lead 703a to the electrode 701a of the semiconductor IC chip 701, and the other of which is a step for forming the solder bump 706 on the land 703b (see FIG. 22). Further another problem associated with the TAB technique is the fact that a sealing step of the semiconductor IC chip 701 provided in the device hole 702b with the sealing resin 705 is also troublesome. Further another problem is the fact that a mounting area is liable to be larger since the base film whose area is larger than that of the semiconductor IC chip 701 is used in this technique.

### SUMMARY OF THE INVENTION

It is, therefore, a main object of the present invention to provide a semiconductor module and a process for producing the same by means of a novel fine-pitch connection technique which is different from the wire bonding technique, the flip chip bonding technique and the TAB technique. Another object of the present invention is to provide a film interposer which is obtained by using of such a novel fine-pitch connection technique.

In order to achieve the object, the present invention provides a semiconductor module, comprising:

a semiconductor element (or a plurality of semiconductor elements) having a principal face on which an element electrode is formed; and

a film member composed of an insulating resin layer having a front face and a rear face which is opposite to the front face, and a wiring pattern formed on the rear face of the layer (i.e. a wiring pattern embedded in the layer on the rear face),

wherein the semiconductor element is superposed on the film member so that the principal face of the semiconductor element is in contact with the front face of the insulating resin layer of the film member; and

a part of the wiring pattern of the film member extends through the insulating resin layer, so that said part is in contact with the element electrode of the semiconductor element.

In this semiconductor module, a pitch is defined or formed by means of the wiring pattern of the film member, and thus the fine-pitch is relatively easy to achieve. Incidentally, a junction obtained due to being in contact between a part of the wiring pattern and the element electrode serves to electrically interconnect the wiring pattern and the element electrode, and thereby the film member used in the present invention serves as an intermediate board located between the semiconductor element and the wiring board (e.g. motherboard). Therefore, the term “film member” is hereinafter referred to as a film interposer.

Such semiconductor module is produced by a process comprising the steps of:

(a) preparing a semiconductor element (or a plurality of semiconductor elements) having a principal face on which an element electrode is formed;

(b) preparing a film member composed an insulating resin layer having a front face and a rear face which is opposite to the front face, and a wiring pattern formed on the rear face of the insulating resin layer;

(c) superposing the semiconductor element on the film member so that the principal face of the semiconductor element is in contact with the front face of the insulating resin layer of the film member; and

(d) pressing a part of the wiring pattern into the film member so that said part is in contact with the element electrode of the semiconductor element.

This process is a novel process for producing a semiconductor module in that it differs from the wire bonding technique, the flip chip bonding technique and the TAB technique of the prior art. According to the process, there is provided not only the above-mentioned semiconductor module but also a film interposer.

In a preferred embodiment, it is preferred that the film member be transparent. For example, the film member is made of a transparent resin such as a polyimide resin or an aramid resin, in which case the step (d) can be visually carried out. That is to say, an alignment between a part of the wiring pattern and the electrode of the semiconductor element is visually performed through the transparent film member. Incidentally, the insulating resin layer of film member may be a coating film obtained by applying an insulating resin over the principal face of the semiconductor element.

By pressing a part of the wiring pattern toward the interior of the insulating resin layer by means of a pressing tool (or pressure welding tool), said part of the wiring pattern extends through the insulating resin layer so that said part is in contact with the element electrode of the semiconductor element. Therefore, a cross-section of said part of the wiring pattern (i.e. cross-section of the junction) may be generally “U” in shape.

It is preferred that an ultrasonic wave be applied to the junction obtained by the pressing, in which case an ultrasonic bonding of the junction is formed. Prior to applying the ultrasonic wave, a plurality of metals may be disposed around the junction (i.e. around or on said part of the wiring pattern), which metals are selected from the group consisting of an aluminum, a gold, a silver, a platinum and a vanadium. In this case, during the application of the ultrasonic wave, the junction is melted to contain an alloy consisting of the above-mentioned plurality of metals and the wiring material (e.g. copper). It is preferred that a physical characteristic of said part of the wiring pattern be measured during the application of the ultrasonic wave. This leads to an understanding of the strength of the junction during pressing a part of the wiring patterns. As a result, the ultrasonic wave can be applied to such a degree that a desired strength of the junction is obtained.

In a preferred embodiment, a front face of the film member and a rear face of the film member which face is opposite to the front face may be approximately the same as the principal face of the semiconductor element in size. This will lead to achievement of a semiconductor module having a relatively small mounting area.

In a preferred embodiment, a front face of the film member and a rear face of the film member which face is opposite to the front face may be larger than the principal face of the semiconductor element in size. In this case, it is preferred that a solder ball be formed on the rear face of the film member.

In a preferred embodiment, the semiconductor of the present invention can further comprise a conventional interposer that is electrically connected to a wiring board wherein the film member is electrically connected to the interposer.

In a preferred embodiment, another film member may be superposed on said film member so that they are laminated to each other. In this case, the film member is considered as a film interposer, which will lead to achievement of a semiconductor module comprising a multilayer film interposer. The semiconductor element in this case may be a semiconductor wafer.

In a first modified embodiment of the above-mentioned semiconductor module and film interposer, there is provided a semiconductor module, comprising:

a semiconductor element having a principal face on which an element electrode is formed and a rear face of the semiconductor element which face is opposite to the principal face;

a film member composed of an insulating resin layer having a front face and a rear face which is opposite to the front face, and a wiring pattern formed on the rear face of the insulating resin layer; and

a wiring board,

wherein the semiconductor element is mounted on the wiring board so that the rear face of the semiconductor element is in contact with the wiring board;

a front face of the film member and a rear face of the film member which face is opposite to the front face are larger than the principal face of the semiconductor element in size;

the film member is mounted over the semiconductor element so that the principal face of the semiconductor element is in contact with the front face of the insulating resin layer of the-film member;

the film member extends up to the wiring board around the semiconductor element; and

at least a part of the wiring pattern of the film member extends through the insulating resin layer so that said part of the wiring pattern is in contact with the element electrode of the semiconductor element, whereas at least a part of the wiring pattern other than said part of the wiring pattern extends through the insulating resin layer so that said at least a part of the wiring pattern other than said part of the wiring pattern is in contact with an electrode formed on said wiring board.

In a second modified embodiment of the above-mentioned semiconductor module, there is provided a semiconductor module, comprising:

a semiconductor element having a principal face and a rear face which is opposite to the principal face, on each of which an element electrode is formed; and

a film member composed of an insulating resin layer having a front face and a rear face which is opposite to the front face, and a wiring pattern formed on the rear face of the insulating resin layer,

wherein the front face of the insulating resin layer of the film member is in contact with the principal face as well as the rear face of the semiconductor element so that the film member extends from the principal face of the semiconductor element through around a side face of the semiconductor element up to the rear face of the semiconductor element;

at least a part of the wiring pattern of said film member extends through said insulating layer so that said part is in contacted with the element electrode formed on the principal face of said semiconductor element; and

at least another part of the wiring pattern of said film extends through said insulating resin layer so that said at least another part of the wiring patter is in contact with the element electrode formed in the rear face of said semiconductor element.

To sum up the above, according to the present invention, there is provided a semiconductor module wherein the principal face of the semiconductor element is in contact with the front face of the film member having the wiring pattern formed on the rear face thereof, and a part of the wiring pattern of the film member extends through the insulating resin layer so that said part is in contact with the element electrode of the semiconductor element. Therefore, there is also provided a fine-pitch connection technique that differs from the wire bonding technique, the flip chip bonding technique and the TAB technique.

### BRIEF DESCRIPTION OF THE DRAWINGS

The foregoing objects, features and advantages of the present invention will become apparent to those skilled in the art from the following detailed description of preferred embodiments thereof, taken in conjunction with the accompanying drawings, in which:

FIG. 1 schematically shows a cross-sectional view of a configuration of a semiconductor module 100 according to an embodiment of the present invention.

FIG. 2 schematically shows a cross-sectional view of a configuration of a semiconductor module 100 according to an embodiment of the present invention.

FIG. 3 schematically shows a cross-sectional view of a configuration of a semiconductor module 100 according to an embodiment of the present invention.

FIG. 4 schematically shows a perspective view of a configuration of a semiconductor module 100 according to an embodiment of the present invention.

FIG. 5 schematically shows a perspective view of a configuration of a semiconductor module 100 according to an embodiment of the present invention.

FIGS. 6(a) to (d) show cross-sectional views illustrating the steps in a process for producing a semiconductor module 100.

FIG. 7 schematically shows a cross-sectional view of a configuration of a semiconductor module 100 according to an embodiment of the present invention.

FIGS. 8(a) to (c) show cross-sectional views illustrating the steps in a process for producing a semiconductor module 100.

FIGS. 9(a) and (b) show cross-sectional views illustrating the steps in a process for producing a semiconductor module 100.

FIGS. 10(a) to (c) show cross-sectional views illustrating the steps in a process for producing a semiconductor module 100.

FIGS. 11(a) and (b) show cross-sectional views illustrating the steps in a process for producing a semiconductor module 100.

FIGS. 12(a) and (b) show cross-sectional views illustrating the steps in a process for producing a semiconductor module 100.

FIG. 13 schematically shows a cross-sectional view of a modified example of a semiconductor module 100 according to an embodiment of the present invention.

FIG. 14 schematically shows a cross-sectional view of a modified example of a semiconductor module 100 according to an embodiment of the present invention.

FIG. 15 schematically shows a cross-sectional view of a modified example of a semiconductor module 100 according to an embodiment of the present invention.

FIG. 16 schematically shows a cross-sectional view of a modified example of a semiconductor module 100 according to an embodiment of the present invention.

FIG. 17 schematically shows a cross-sectional view of a modified example of a semiconductor module 100 according to an embodiment of the present invention.

FIG. 18 shows a cross-sectional view of an electronic circuit device 200 disclosed in the publication.

FIG. 19(a) shows a top view of an embodiment of a conventional wire bonding technique, and also FIG. 19(b) shows a cross-sectional view of the embodiment taken along the line A-A shown in FIG. 19(a).

FIG. 20 shows a cross-sectional view of a resin sealing body (semiconductor module) 500 of the prior art.

FIG. 21 shows a cross-sectional view of a semiconductor device 600 obtained by means of a flip chip bonding technique of the prior art.

FIG. 22 shows a cross-sectional view of a semiconductor device 700 obtained by means of a TAB technique of the prior art.

FIG. 23 shows a cross-sectional view of an embodiment wherein the semiconductor device 700 shown in FIG. 22 is mounted on the substrate 709.

In the drawings, the reference numbers correspond to the following elements: 10 . . . film interposer (film member), 11 . . . insulating resin layer, 11′ . . . coating film, 12 . . . element electrode, 18 . . . carrier sheet, 19 . . . metal layer, 20 . . . wiring pattern, 22, 23 . . . a part of wiring pattern, 24 . . . land, 25 . . . interlaminar junction, 26 . . . wiring, 28 . . . terminal, 30 . . . semiconductor element, 30a . . . principal face of semiconductor element (electrode-forming surface), 32 . . . element electrode, 35 . . . semiconductor wafer, 40 . . . solder ball, 41 . . . wiring board, 42 . . . electrode of wiring board, 45 . . . interposer, 50 . . . pressing tool, 100 . . . semiconductor module, 200 . . . electronic circuit device, 205a . . . external electrode terminal layer, 207 . . . insulating resin layer, 209 . . . wiring circuit conductive layer, 500 . . . semiconductor module (semiconductor element), 600 . . . semiconductor device and 700 . . . semiconductor device.

### DETAILED DESCRIPTION OF THE PREFERRED EMBODIMENTS

With reference to the attached figures, a few embodiments of the present invention will be hereinafter described in more detail. As to the drawings, the constituent elements having a substantially similar function carry the same reference number for ease of the description. It will be noted that the present invention will not necessarily be limited to the following embodiments.

### Embodiment 1

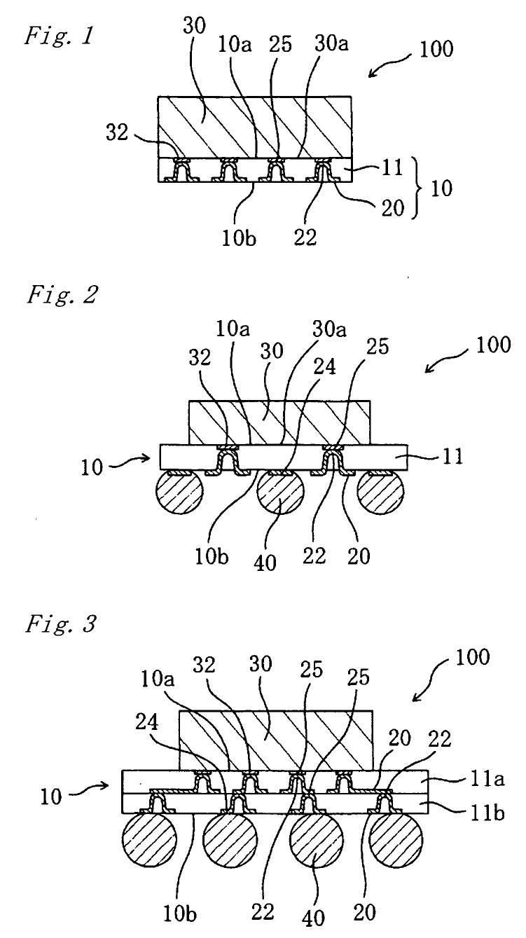

Turning now to FIG. 1, the semiconductor module 100 according to this embodiment of the present invention will be described. FIG. 1 schematically shows a cross-sectional view of a configuration of a semiconductor module 100 according to this embodiment of the present invention.

The semiconductor module 100 shown in FIG. 1 is composed of the semiconductor element 30 and the film member 10. The semiconductor element 30 has the element electrodes 32 on the front face 30a thereof. Such front face 30a of the semiconductor element, on which face the element electrode 32 is formed, is hereinafter referred to as “principal face”. The film member 10 is composed of the insulating resin layer 11 and the wiring patterns 20 wherein the wiring patterns 20 are formed on the rear face 10b of the insulating resin layer 11 (i.e. on the rear face of the film member 10). The wiring patterns 20 may be embedded or buried in the insulating resin layer 11 on the rear face 10b, in which case it is preferred that the surface of the wiring patterns 20 be flush (or approximately flush) with the surface of the rear face of the insulating resin layer 11.

As shown in FIG. 1, in the semiconductor module 100, the semiconductor element 30 is superposed on the film member 10 so that the principal face 30a of the semiconductor module 30 is in contact with the front face 10a of the film member 10 (i.e. with the front face of the insulating resin layer 11). Furthermore, a part 22 of the wiring pattern 20 of the film member 10 extends through the insulating resin layer 11 so that said part 22 is in contact with the element electrode 32 of the semiconductor element 30.

The semiconductor element 30 used in the semiconductor module 100 of the present invention may be a semiconductor bare chip or a chip size package (CSP), for example. The thickness of the semiconductor element 30 may be for example 20 to 400 μm, preferably 50 to 400 μm. To be more specific, the semiconductor element 30 may be a memory IC chip, a logic IC chip, a system LSI chip or a LED chip (i.e. light emitting diode chip).

It is preferred that the element electrode 32 formed on the principal face 30a of the semiconductor module 100 be made of Al or Au, in which case the thickness of the element electrode may be for example 0.01 to 0.1 μm, preferably 0.05 to 0.1 μm.

The insulating resin layer 11 of the film member 10 used in the semiconductor module 100 of the present invention may be made of an insulating resin used for a conventional semiconductor module. Preferably, the insulating resin layer 11 is made of a transparent insulating resin, and thereby it is preferably made of a film (or core film) consisting of a polyimide or an aramid. Furthermore, the insulating resin layer 11 may be made of a polyphenylene sulfide (PPS), a polypropylene or a polymethl methacrylate. It will be noted that the insulating resin layer 11 may contain any other resin or material in addition to the above resin or material. The thickness of the insulating resin layer 11 is for example 1 to 30 μm, preferably 1 to 10 μm.

The wiring pattern 20 of the film member 10 used in the semiconductor module 100 of the present invention is preferably made of a copper, for example. The thickness of the wiring pattern 20 is preferably 1 to 35 μm, more preferably 1 to 12 μm.

In the semiconductor module 100 shown in FIG. 1, the front face 10a of the film member 10 and the rear face 10b of the film member 10 which face is opposite to the front face 10a are approximately the same as the principal face 30a of the semiconductor element 30. Furthermore, the semiconductor element 30 and the film member 10 are stacked on each other so that the principal face 30a of the semiconductor element 30 is in contact with the front face 10a of the film member 10. The size of each of the front face 10a and rear face 10b of the film member 10 is for example 1 to 10 mm×1 to 10 mm, preferably 3 to 10 mm×3 to 10 mm. As with the size of the film member 10, the size of the principal face 30a of the semiconductor element 30 is for example 1 to 10 mm×1 to 10 mm, preferably 3 to 10 mm×3 to 10 mm.

In order to obtain the semiconductor 100 shown in FIG. 1, a part 22 of the wiring pattern 20 is pressed toward the interior of the insulating resin layer 11 by means of a needle-like member, for example. As a result, such part 22 of the wiring pattern 20 extends through the insulating resin layer 11 so that a cross-section of the part 22 of the wiring pattern 20 is generally “U” in shape. It will be noted that such cross-section may also have various types of shapes, depending on the pressing condition of the part 22 of the wiring pattern 20.

In the semiconductor module 100, said part 22 of the wiring pattern 20 is in contact with the element electrode 32 of the semiconductor element 30, and preferably they are jointed or pressure-welded to each other. Thus, the resulting junction 25 serves to electrically interconnect the element electrode 32 of the semiconductor element 20 and the wiring pattern 20 of the film member 10. The term “junction” is also hereinafter referred to as “interlaminar junction”. As described above, the film member 10 corresponds to “film interposer” or “filmy interposer” since the film member 10 serves as an intermediate board located between the semiconductor element 30 and the wiring board (e.g. motherboard). Therefore, the film interposer of the present invention is composed of a sheet-like film (e.g. transparent or translucent film) 11 consisting of an insulating resin and the wiring patterns 20 formed on one face (i.e. rear face 10b) of the film 11, in which case a part 22 of the wiring pattern 20 extends through the film 11 so that said part 22 is exposed on the front face 10a of the film 11. A cross-section of the part 22 of the wiring pattern 20 is generally “U” in shape, in which case the bottom part of said “U”-shaped wiring pattern 20 is in contact with (or connected to) the element electrode 32 of the semiconductor element 30.

In this way, for the purpose of producing the semiconductor module 100 of the present invention, a connection technique using the film interposer is performed. It will be understood that such connection technique is different from the wire bonding technique, the flip chip bonding technique and the TAB technique.

Hereinafter, the applied or modified examples of the above-mentioned semiconductor module of the present invention will be described.

In the semiconductor 100 of the present invention, some solder balls 40 may be formed on the rear face of the film member 10. It is preferred that the solder balls 40 be two-dimensionally arranged. As shown in FIG. 2, the solder balls 400 may be mounted on the lands 24 of the wiring patterns 20. In this case, the semiconductor module 100 is mounted on a wiring board (not shown in FIG. 2) via such solder balls 40. The land on which the solder ball 40 is mounted is electrically connected to the generally “U”-shaped interlaminar junction 20 via a predetermined wiring (not shown in FIG. 2).

In the embodiment shown in FIG. 2, the film interposer 10 (i.e. film member) is configured to have a larger size than that of the principal face 30a of the semiconductor element 30. As a result, a pitch that is broader than that of the element electrode 32 in the semiconductor element 30 can be provided on the land 24 of the film interposer 10, and thereby a so-called “fan-out” can be easily achieved. In this case, each of the front face 10a and the rear face 10b of the film member 10 has a size of for example 3 to 15 mm×3 to 15 mm, preferably 5 to 15 mm×5 to 15 mm. The principal face 30a of the semiconductor element 30 has a size smaller than for example 3 to 15 mm×3 to 15 mm, preferably a size smaller than 5 to 15 mm×5 to 15 mm.

As to the embodiment shown in FIG. 1 wherein the principal face 30a of the semiconductor element 30 is approximately the same as the front face 10a and rear face 10b of the film interposer 10, the solder ball 40 can be mounted on the film interposer 10. In this case, the land 24 is formed on a predetermined area of the wiring pattern 20 provided on the rear face 10b of the film interposer 10.

Even in the case where the principal face 30a of the semiconductor element 30 is approximately the same the front face 10a of the film interposer, a broader pitch than that of the element electrode 32 of the semiconductor element 30 can be obtained, when the wiring patterns 20 are arranged to form the grid alignment of lands on the film interposer 10 in which case the element electrodes 12 are arranged on the peripheral part of the semiconductor element 30.

Furthermore, in the case where the semiconductor element 30 is used as a semiconductor bare chip, a so-called PGA (pin grid array) package or BGA (ball grid array) package can be easily obtained when the film interposer 10 having the two-dimensionally arranged wiring pattern 20 (typically, the film interposer 10 having the grid alignment of the wiring patterns 20) is used. In addition, in the case of the semiconductor module 100 having a configuration shown in FIG. 1, a so-called CSP (e.g. BGA-type CSP) can be easily obtained.

In the semiconductor module 100 shown in FIG. 3, another further film member is superposed on the rear face 10b of the film member 10 shown in FIG. 1 for example. Thus, the semiconductor module 100 shown in FIG. 3 comprises a multilayer film interposer 10. This means that the multilayer film interposer 10 is composed of a first film 11a and a second film 11b as shown in FIG. 3. Each of them has the wiring patterns 20 and the interlaminar junctions. On the rear face 10b of the film interposer 10, some lands 24 are formed wherein each of the solder balls 40 is mounted on each of the lands 24. In this case of the semiconductor module 100 shown in FIG. 3, it is preferred that the semiconductor element be a semiconductor wafer.

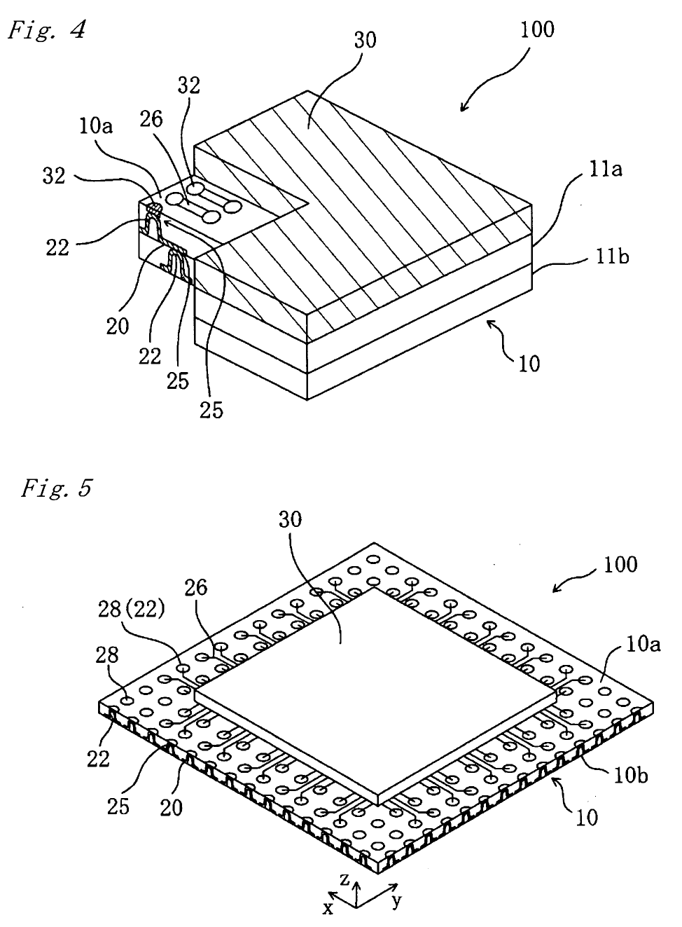

FIG. 4 schematically shows a perspective and cutaway view of a configuration of the semiconductor module 100 of the present invention. The shown film interposer 10 has a multilayer structure composed of the first film 11a and the second film 11b. In the semiconductor module 100 as shown in FIG. 4, the front face 10a of the film interposer 10 is approximately the same as the principal face 30a of the semiconductor element 30 in size.

In FIG. 4, a few interlaminar junctions 25 are shown. For the purpose of convenience, the electrode 32 of the semiconductor element 30 is alternatively shown on the film interposer 10 in FIG. 4. As shown, the wire (or wiring patterns) 26 can be used to form an electrical pathway on the front face 10a of the film interposer 10.

As with FIG. 4, FIG. 5 schematically shows a perspective and cutaway view of another configuration of the semiconductor module 100 of the present invention. In FIG. 5, an edge region of the film interposer 10 is partially cut away so as to facilitate visualization of the structure of the interlaminar junction 25. The shown semiconductor module 100 is a BGA module (or PGA module) whose terminal has more than and equal to 100 pins. In this semiconductor module 100, the fan-out regarding the element electrodes 32 of the semiconductor element 30 is achieved by means of the film interposer 10.

In the configuration of FIG. 5, a terminal 28 (e.g. land) is formed on the front face 10a of the film interposer 10 so that a part 22 of the wiring pattern 20 is exposed on the front face 10a via the terminal 28. This means that said part 22 of the wiring pattern 20 is not directly exposed on the front face 10a of the film interposer 10. As shown in FIG. 5, the terminal 28 is electrically connected to the wire 26 formed on the front face 10a of the film interposer 10. In the meanwhile, in the overlapping region between the semiconductor element 30 and the film interposer 10, a part 22 of the wiring pattern 20 is directly connected to the element electrode of the semiconductor element 30 without the terminal 28.

In the embodiment shown in FIG. 5, the fan-out is achieved by forming the wires 26 and the terminals 28 on the front face 10a of the film interposer 10. Instead of that, it will be noted that the fan-out can be also achieved by means of the wiring patterns 20 formed on the rear face 10b of the film interposer 10 and the interlaminar junction 25.

Unlike the case where the interlaminar junction 25 is composed of a via consisting a conductive paste material, the interlaminar junction 25 according to the present invention prevents a discordance of an impedance between wirings (wiring patterns) and vias (interlaminar junctions) because the interlaminar junction in the latter case consists of the same material as the wiring patterns in a seamless state. Also, due to fact that the interlaminar junctions 25 are made of the same material as that of the wiring patters 20 in the present invention, there is no difference between a thermal expansion coefficient of the interlaminar junction 25 and that of the wiring pattern 20, which will lead to a better reliability in connection.

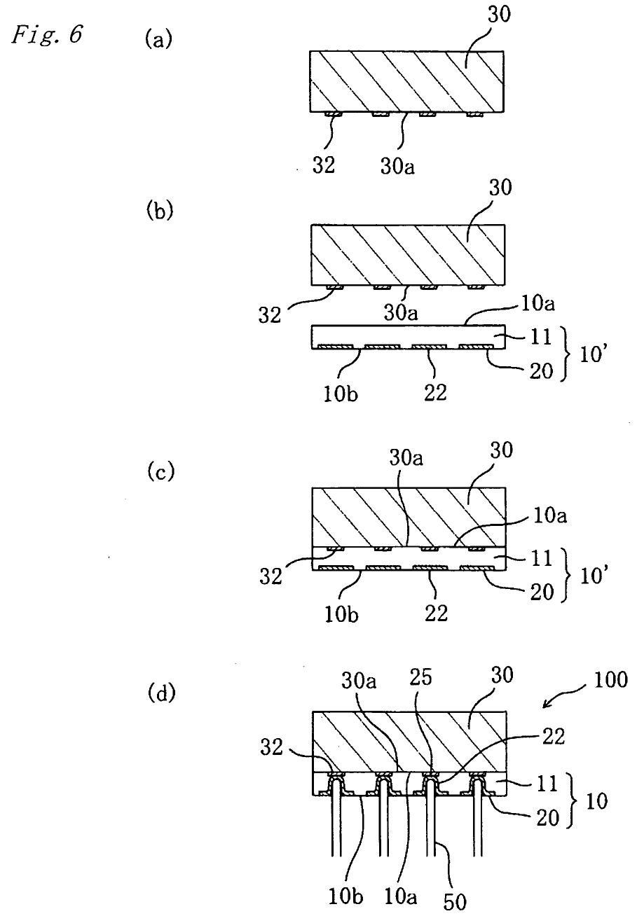

Turning now to FIGS. 6(a) to (d), the production process of the semiconductor module 100 according to the present invention will be hereinafter described. FIGS. 6(a) to (d) show cross-sectional views illustrating the steps in a process for producing a semiconductor module 100 shown in FIG. 1.

First, as shown in FIG. 6(a), the semiconductor element 30 (e.g. bare chip) having the element electrodes 32 formed on the principal face 30a is prepared. As shown in FIG. 6(b), the film member 10′ to be combined with the semiconductor element 30 is also prepared. On the rear face 10b of the film member 10′, the wiring patterns 20 are formed in such a manner that a part 22 of each of the wiring patterns 20 is configured to correspond to each of element electrodes 32 of the semiconductor element 30 in the following steps.

Next, as shown in FIG. 6(c), the semiconductor element 30 is superposed on the film member 10′ so that the principal face 30a of the semiconductor element 30 is in contact with the front face 10a of the film member 10′. Subsequently, as shown in FIG. 6(d), a part 22 of each of the wiring patterns 20 of the film member 10′ is pressed toward the interior of the insulating resin layer 11 of the film member 10′ so that said part 22 extends through the insulating resin layer 11. As a result, said part 22 of the wiring pattern 20 is in contact with each of the electrodes 32 of the semiconductor element 30. In the case of the embodiment shown in FIG. 6, a part 22 of the wiring pattern 20 is pressed toward the interior of the insulating resin layer 11 of the film member 10′ by means of a pressing tool 50 such as a needle-like member. Thus, a cross-section of the resulting junction 25 is generally “U” in shape. In the case where the needle-like member is used, it is preferred that a pressing portion thereof (i.e. tip of the needle-like member) be hemispherical in shape. The diameter of the needle-like member is for example 10 to 200 μm, preferably 10 to 50 μm. It will be noted that the needle-like member having a planar tip can be used.

Through the above-mentioned steps, the semiconductor module 100 of the present invention can be obtained. It will be understood that the film interposer 10 as shown in FIG. 6(d) can be finally obtained in the production process of the semiconductor module 100.

In the embodiment of the present invention, the film 11 (i.e. insulating resin layer 11) of the film member 10′ is made of a polyimide or an aramid for example, in which case the film 11 is substantially transparent. Therefore, during the step for superposing the semiconductor 30 on the film member 10′, an alignment between the element electrode 32 and a part 22 of the wiring pattern 20 is easy to perform since the element electrode 32 can be seen through the transparent film 11.

It is possible to apply an ultrasonic wave upon pressing of the wiring patterns with the pressing tool 50. The application of the ultrasonic wave causes a contacting area of the interlaminar junction 20 to be ultrasonically-bonded, which will lead to achievement of the semiconductor module having a better connecting reliability. For example, in the case where the pressing tool 50 provided with a function of applying an ultrasonic wave is used, it is possible to carry out a pressing process and an ultrasonically-bonding process simultaneously. In order to obtain a stronger junction caused by the application of the ultrasonic wave, some metals (e.g. an aluminum, a gold, a silver, a platinum and/or a vanadium) except for copper of the wiring pattern may be disposed around a part 22 of the wiring pattern 20. This means that the resulting interlaminar junction 25 can contain an alloy consisting of the plural metals selected from the group consisting of a copper an aluminum, a gold, a silver, a platinum and a vanadium, due to the fact that such metals are melted when the ultrasonic wave is applied.

The frequency of the ultrasonic vibration is for example 40 kHz to 1 MHz, preferably 40 to 800 kHz. The generating power is for example 10 to 50 W, preferably 20 to 40 W. Furthermore, the applying time is for example 0.1 to 1 second, preferably 0.1 to 0.5 second.

It is preferred that a physical characteristic of a part of the wiring pattern 20 be measured during the application of the ultrasonic wave. The measured physical characteristic is a resistance of a part of each wiring pattern 20, or a degree of the dent or depression of each wiring pattern 20, for example. In the case where the application of the ultrasonic wave and the measurement of the physical characteristic (e.g. resistance) are concurrently carried out, a strength characteristic of the interlaminar junction 25 can be obtained in real time. This allows the ultrasonic wave to be applied to such a degree that a desired strength of the interlaminar junction 25 is obtained. It is only necessary to carry out the measurement of the physical characteristic at first one time or a few times, in which case, on the basis of the result of such measurement, an amount of the energy of the ultrasonic wave or a applying time and the like can be subsequently adjusted.

In the semiconductor module of the present invention and the process for the same, the junction ensures an electrical connection between a part of the wiring pattern 20 and the semiconductor module 30. Therefore, a procedure for a wire connection using thin metallic lines (gold wire) one by one, which is peculiar to the wire bonding technique, is excluded from the present invention. This results in a less labor for a process operation, compared with the wire bonding technique. To put it more clearly in perspective, in recent years, the number of the pins (input-output terminals) used in the semiconductor has been substantially increasing. It is speculated that the number of the pins will reach to 1000 (i.e. 1000 pin) in 2006, and reach to 2000 (i.e. 2000 pin) in 2010. It will be therefore understood that the wire bonding technique will be very hard to perform in terms of a handling or processing for lots of pins. In the meanwhile, the semiconductor module of the present invention and the process for the same are advantageous in that lots of pins are easy to handle or process because lots of interlaminar junctions can be obtained all at once by means of a plurality of the needle-like members.

The semiconductor module of the present invention and the process for the same are advantageous in that the pitch can be defined by the wiring patterns 20, and thereby a fine-pitch connection technique whose pitch is finer than that for the case of the wire bonding technique can be achieved. It is speculated that the pin pitch of the semiconductor element will reach to 40 μm in 2006, and also reach to 20 μm in 2010. Therefore, the wire bonding technique will be very hard or virtually impossible to perform in terms of a handling for such fine-pitch, considering the diameter of the gold wire. In this respect, the semiconductor module of the present invention and the process for the same are advantageous in that such fine-pitch is easy to achieve because the fine pitch in this case can be defined or obtained by means of the wiring patterns.

Furthermore, the semiconductor module of the present invention and the process for the same are advantageous in that a mounting area can be smaller than that of the semiconductor for the case of the wire bonding technique because the film interposer can be properly superposed on the semiconductor element (e.g. bare chip). For example, on the basis of the semiconductor module 100 shown in FIG. 1, it is possible to obtain a real-sized CSP having the same size as that of the principal face 30a of the semiconductor element (bare chip) 30. Moreover, it is possible to obtain the semiconductor module having a lower height than that for the case of the wiring bonding technique due to the connection technique using the film interposer 10. This will contribute to achievement of a thinner semiconductor module.

Furthermore, the semiconductor module of the present invention and the process for the same are advantageous in that the position or arrangement of the element electrode 32 of the semiconductor element 30 can be confirmed through the transparent film 11 upon superposing the semiconductor 30 on the film member 10′. That is to say, an alignment is easy to perform, compared with the case of the flip chip bonding technique. As a result, the semiconductor module of the present invention and the process for the same are easy to meet a tolerance requirement concerning the semiconductor element, compared with the case of the flip chip bonding technique.

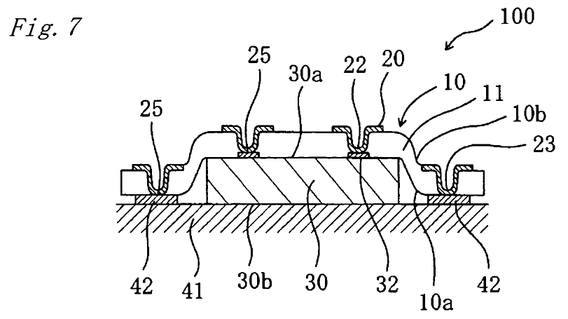

As shown in FIG. 7, particularly in the case of the semiconductor module wherein the semiconductor element 30 is superposed on the wiring board 41 so that a rear face 30b (i.e. the face opposite to the principal face 30a) of the semiconductor element 30 is in contact with the wiring board 41, and also the film interposer 10 (i.e. film member) extends up to the wiring board 41 around the semiconductor element 30, a part 23 of the wiring pattern 20 of the film interposer 10 can extend through the insulating resin layer so that the part 23 is electrically connected to the electrode 42 of the wiring board 41, not the electrode 32 of the semiconductor element 30. That is to say, in this case, not only the alignment between the part 23 of the wiring pattern 20 and the element electrode 32, but also the alignment between the part 23 of the wiring pattern 20 and the electrode 42 of the wiring board 41 is visually performed through the transparent film 11. This is why the semiconductor module of the present invention and the process for the same have a high technical value. Incidentally, the term “visually” means that the alignment is performed not only with an operator's eyes, but also by an image recognition device (e.g. a device comprising CCD or CMOS sensor).

In the configuration of FIG. 7, the semiconductor module 100 comprises:

a semiconductor element 30 having a principal face 30a on which an element electrode 32 is formed and a rear face 30b of said element which face is opposite to said principal face 30a;

a film member 10b composed of an insulating resin layer 11 having a front face 10a of said layer 11 and a rear face 10b of said layer 11 which face is opposite to said front face 10a, and a wiring pattern 20 formed on the rear face 10b of said insulating resin layer 11; and

a wiring board 41,

wherein said semiconductor element 30 is mounted on said wiring board 41 so that the rear face 30b of said semiconductor element 30 is in contact with said wiring board 41;

a front face 10a of said film member 10 and a rear face 10b of said film member 10 which face is opposite to said front face 10a are larger than the principal face 30a of said semiconductor element 30 in size, and said film member 10 is mounted over said semiconductor element 30 so that the principal face 30a of said semiconductor element 30 is in contact with the front face 10a of said film member 10, said film member 10 extending up to said wiring board 41 around said semiconductor element 30;

at least a part 22 of the wiring pattern 20 of said film member 10 extends through said insulating resin layer 11 so that said part 22 of the wiring pattern 20 is in contact with the element electrode 32 of said semiconductor element 30, whereas at least a part 23 of the wiring pattern 20 extends through said insulating resin layer 11 so that said part 23 of the wiring pattern 20 is in contact with an electrode 42 formed on said wiring board 41.

In the case of the flip chip bonding technique, the connection between the semiconductor element and the wiring board is hard to visually confirm due to the fact that the electrode-forming surface of the semiconductor element faces toward the wiring pattern of the wiring board. In the meanwhile, in the case of the semiconductor as shown in FIG. 7 for example, the connection between the semiconductor element 30 and the wiring board 41 is easy to visually confirm because the interposer 10 (i.e. film member 10) is composed of the transparent film 11.

The semiconductor module of the present invention and the process for the same are advantageous in that the cost concerning the wiring board is alleviated compared with the case of the flip chip bonding technique, because the fine-patterned wirings, which are supposed to be formed on the wiring board for the case of the flip chip bonding technique, can be formed on the film interposer (i.e. film member) in the case of the present invention. Furthermore, in the case of the flip chip bonding technique, the more the number of the terminals increases at a particular region (i.e. the wiring board region facing toward the principal face of the semiconductor element), the more the number of layers of the wiring boards is required. Meanwhile, in the case of the semiconductor module of the present invention and the process for the same, the wiring can be provided by means of the wiring pattern of the film interposer, which leads to less number of layers of the wiring boards. From this standpoint, the cost of the wiring board is furthermore alleviated in the case of the semiconductor module of the present invention and the process for the same. According to the present invention, a multilayer film interposer can be obtained with comparative ease, as shown in FIGS. 3 or 4. In addition, as shown in FIGS. 2, 3 and 5, the fan-out using the film interposer 10 allows the production cost to go down when the degree of the fine-pith formed on the wiring board 41 is lowered.

The semiconductor module of the present invention and the process for the same are advantageous in that the matching between a linear thermal expansion coefficient of the semiconductor element 30 and that of the film interposer 10 is relatively alleviated, compared with the case of the flip chip bonding technique. That is to say, the film interposer (or film) of the present invention is so thin that it has less effect on the semiconductor element. And also, the flexibility of the film can absorb a stress that may occur due to the disparity between the linear thermal expansion coefficients of the semiconductor element and the film interposer.

Furthermore, the semiconductor module of the present invention and the process for the same are advantageous in that the connection between the semiconductor element and the wiring board is formed without an underfill agent (sealing resin) that is essential in the case of the flip chip bonding technique. It will be noted that, in the case of the semiconductor module of the present invention, the film interposer can protect the principal face of the semiconductor element on which face the element electrodes are formed.

In the semiconductor module of the present invention and the process for the same, a bump (e.g. solder bump or gold bump) may be on the element electrode of the semiconductor element. However, the element electrode having no bump can be alternatively used. Therefore, unlike the case of the flip chip bonding technique, it is possible to electrically interconnect the semiconductor element and the wiring board without forming the bump on the element electrode.

Next, the comparison with the TAB technique will be hereinafter described. In the TAB technique, it is required that the inner lead bonding step and the outer-lead bonding step are independently carried out. In contrast to that, the semiconductor module of the present invention does not require such separate steps. Furthermore, in the case of the semiconductor module of the present invention, there is no need to use the sealing resin used for case of the TAB technique. In addition, a smaller mounting area can be achieved.

Although the examples of the attached figures (e.g. FIG. 1) illustrate a few element electrodes 32 for descriptive purpose, the number of the element electrodes is not limited. Even in the case of many element electrodes 12, many junctions can be obtained all at once by means of the pressing tool 50 shown in FIG. 6(d). Thus, the more the element electrode is provided, the more valuable the semiconductor module of the present invention becomes in terms of its technical meanings, compared with the case of the wire bonding technique for example. As described above, the element electrodes are arranged on the peripheral part of the semiconductor element, which is however cited merely by way of example and without limitation. That is to say, the element electrodes can be arranged in the form of “array” or “grid alignment”. Furthermore, in the semiconductor module shown in FIG. 7, the generally “U”-shaped interlaminar junction 25 can be formed only for the purpose of connecting the element electrode 32 and the wiring pattern 20, whereas another connection technique (e.g. the technique using a solder such as a low-melting metal) can be performed for the purpose of interconnecting the electrode 42 of the wiring board 41 and the wiring pattern 20.

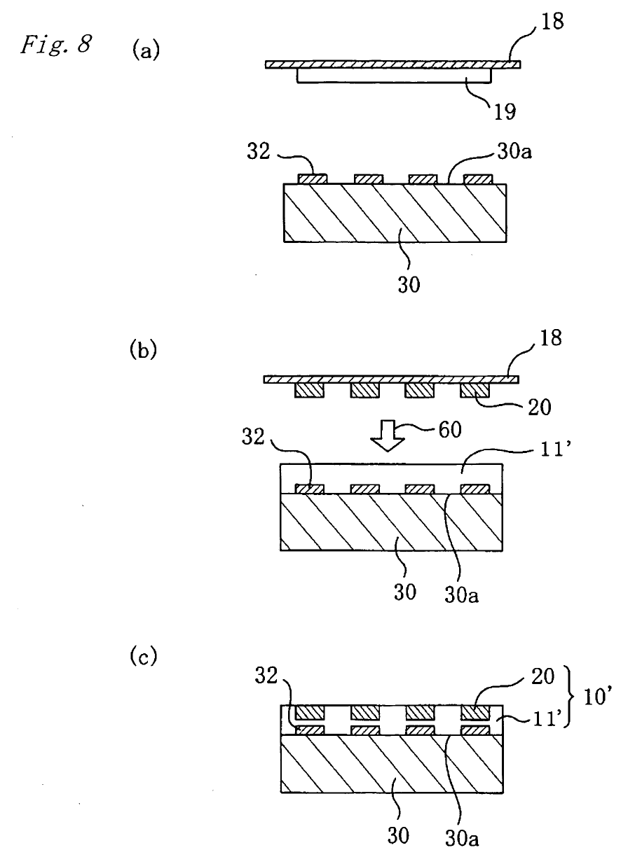

Turning now to FIGS. 8 to 12, another production process of the present invention and semiconductor module obtained by such process will be hereinafter described.

In the production process described above with reference to FIGS. 6(a) to (d), the film member 10′ comprises the insulating resin layer 11, but not limited to that. By applying an insulating resin over the principal face 30a of the semiconductor 30, a coating film can be used as the insulating resin layer 11. The relevant production process will be hereinafter described.

First of all, as shown in FIG. 8(a), the semiconductor element 30 having element electrodes 32 on the principal face 30a thereof is prepared, and also the metal layer (typically copper foil) 19 formed on a carrier sheet 18 is prepared. The term “carrier sheet” here is preferably made of PET (polyethylene terephthalate) or PEN (polyethylene naphthalate) in which case the thickness thereof is about 5 to 15 μm for example.

Subsequently, as shown in FIG. 8(b), a patterning process for forming wiring patterns from the metal layer 19 is carried out. And also, the insulating resin is applied over the principal face 30a of the semiconductor element 30 so that the resulting coating film 11′ covers the element electrodes 32. Incidentally, it is preferred the insulating resin be an adhesive or agglutinant. After that, the wiring patterns 20 formed on the carrier sheet 18 are transferred to the coating film 11′ in the direction indicated by the arrow 60 of FIG. 8(b). As a result, the film member 10′ having wiring patterns 20 is mounted on the principal face 30a of the semiconductor element 30 as shown in FIG. 8(c).

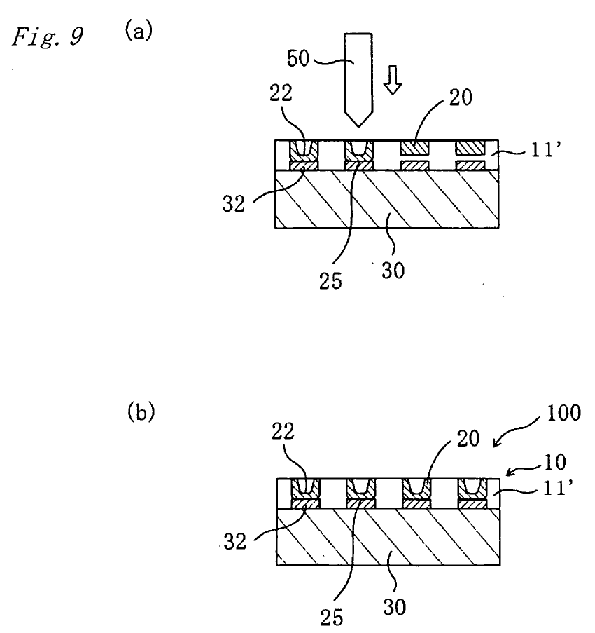

Subsequently, as shown in FIG. 9(a), a part 22 of each of the wiring pattern 20 is pressed toward the interior of the coating film 11′ by means of the pressing tool 50 in order to form the interlaminar junctions 25. As a result, the semiconductor module 100 as shown in FIG. 9(b) is obtained.

According to such process, the coating film 11′ is used as a film 11, and therefore there is no need to prepare the film member 10′ having the wiring patterns 20. In the case where a facility or means for transferring the wiring pattern is already prepared, such production process is relatively convenient.

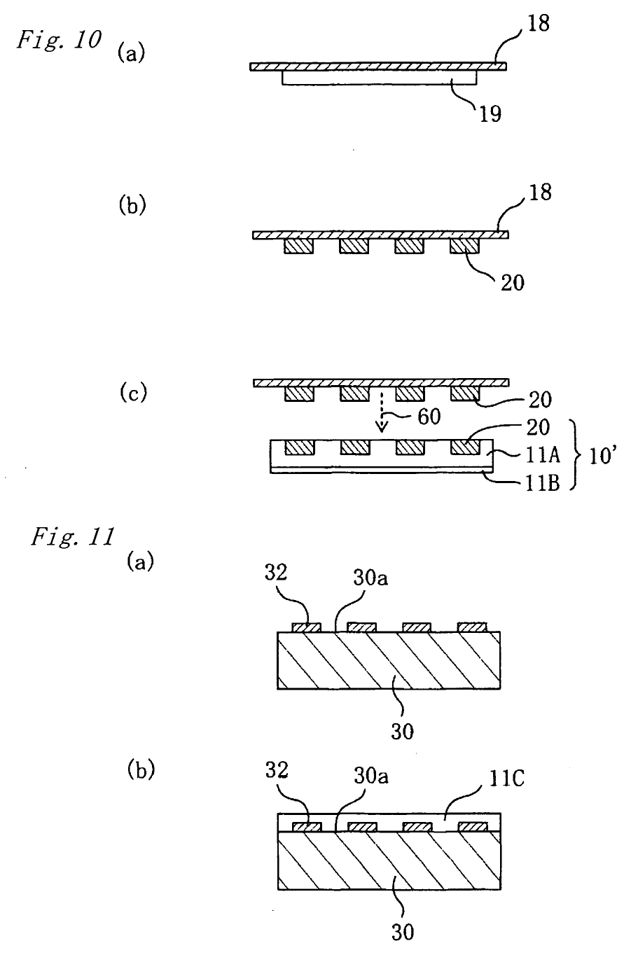

Alternatively, the semiconductor module of the present invention can be produced by means of another process shown in FIGS. 10(a) to 12(b). Such process will be hereinafter described.

First of all, the patterning process for forming wiring patterns 20 from the metal layer 19 on the carrier sheet 18 is carried out (see FIGS. 10(a) and 10 (b)). Subsequently, such wiring patterns 20 are transferred to an insulating resin layer 11A superposed on an film 11B in the direction indicated by the arrow 60 of FIG. 10(c). As a result, the film member 10′ having wiring patterns 20 is obtained. The insulating resin layer 11A is preferably an adhesive layer or agglutinant layer in which case it may be made of an epoxy-resin. In the meantime, the film 11B may be made of a polyimide or an aramid.

In parallel with that, the semiconductor element 30 as shown in FIG. 11(a) is prepared. Subsequently, an insulating resin layer 11C is formed on the principal face 30a of the semiconductor element 30 so that the element electrodes 32 are covered with the layer 11C (see FIG. 11(b)). The insulating resin layer 11C is preferably an adhesive layer or an agglutinant layer in which case it may be made of an epoxy-resin.

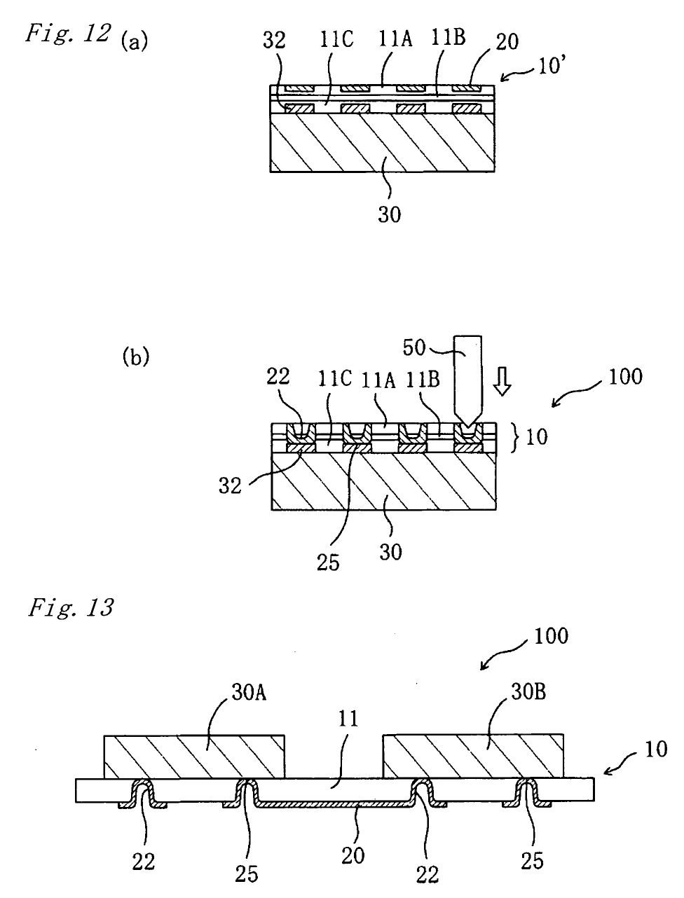

Subsequently, as shown in FIG. 12(a), the film member 10′ is superposed on the insulating resin layer 11C. After that, as shown in FIG. 12(b), the interlaminar junctions 25 are formed by means of the pressing tool 50. As a result, the semiconductor module 100 can be obtained.

Alternatively, the semiconductor module of the present invention can be obtained without the step shown in FIG. 11(b). In this case, the insulating resin layer 11C needs to be formed on the lower surface (i.e. exposed surface) of the film 11B of the film member 10′, not on the principal face 30a of the semiconductor element 30. Subsequently, the resulting lamination (i.e. the resulting film member) is superposed on the principal face 30a of the semiconductor element 30. As a result, the semiconductor module 100 as shown in FIG. 12(a) can be obtained.

As described above, it is preferred that an aramid film be used as the film 11B. The reason for this is that, even in the case where the aramid film is thinner than a polyimide film, a desired strength is easy to achieve, and that the aramid film is cheaper than the polyimide film. To put it another way, the aramid has a high elasticity-strength so that it is suitable for forming a thin film. For example, about 4 μm of the aramid film thickness corresponds to about 12.5 μm of the polyimide film thickness in terms of their strengths. Furthermore, even in terms of a low absorptivity and a dimensional stability, the aramid film is preferable.

The aramid film has a high heat-resisting characteristic. Thus, in the case where the heat-resisting properties are required, it is more preferable to use the aramid film, than to use the polyimide film.

According to the production process using the above-mentioned transferring technique, the resulting wiring patterns 20 are advantageous in terms of a better surface flatness since the wiring patterns are transferred to bury them in the insulating resin layer 11 (or 11A). Furthermore, such transferring technique can give a finer pitch of the wiring pattern than that for the case of a wet etching technique because the wiring patterns 20 made of copper foil are used in the case of the transferring technique. For example, a line/space (L/S) of the wiring patterns for the case of the wet etching technique is 40 μm/40 μm, whereas a line/space (L/S) of the wiring patterns for the case of the transferring technique can be very fine 15 μm/15 μm (i.e. 30 μm pitch).

It will be noted that the wiring patterns 20 obtained by means of the wet etching technique can also be alternatively used. For example, for the purpose of obtaining the film member 10′ as shown in FIG. 6(b), a copper clad laminate (CCL) wherein the copper layer (metal layer) is superposed on the film 11 may be etched. In this case, two-kinds of copper clad laminates can be used, wherein one is a two-layer CCL in which a copper foil is superposed directly on the film 11 without an adhesive layer, the other is a three-layer CCL in which a copper foil is superposed on the film via an adhesive. The CCL is in itself available for the purpose of producing the typical flexible substrate. Thus, the CCL contributes to the reduction of the material cost.

### Embodiment 2

Further another modified embodiment of the present invention will be hereinafter described with reference to FIGS. 13 to 17. For ease of explanation, the relevant matters similar to those of the above-mentioned embodiment 1 will be abbreviated or omitted.

In the above embodiment 1, one semiconductor element 30 is mounted or superposed on one-film interposer 10. In contrast to that, as shown in FIG. 13, a plurality of semiconductor elements (e.g. semiconductor elements 30A and 30B) may be mounted or superposed on one film interposer 10, in which case the resulting semiconductor module 100 can be use as a multichip module. In other word, such semiconductor module comprises:

a semiconductor element having a principal face on which an element electrode is formed;

a film member (i.e. film interposer) composed of an insulating resin layer having a front face and a rear face which is opposite to the front face, and a wiring pattern formed on the rear face of the layer, and

one or more another semiconductor element(s) having a principal face on which an element electrode is formed,

wherein each of said semiconductor elements is superposed on the film member so that the principal face of each of said semiconductor elements is in contact with the front face of the insulating resin layer of the film member; and

a part of the wiring pattern of the film member extends through the insulating resin layer, so that said part is in contact with the element electrode of the former semiconductor element, and also at least another part of the wiring pattern of the film member extends through the insulating resin layer, so that said another part is in contact with the electrode of the latter semiconductor element(s) (i.e. said another semiconductor element(s)).

In the configuration shown in FIG. 13, the semiconductors 30A and 30B can be electrically interconnected by means of a continuous wiring pattern 20 formed in the film interposer 10. This will lead to achievement of a high-speed connection between LSI chips via the film interposer 10, in which case the resulting semiconductor module can have a high-performance function. Incidentally, the element electrode is not shown in FIG. 13.

In the example, shown in FIG. 13, the semiconductor module 100 is produced by using of a combination of the semiconductor elements 30A and 30B, but not limited to that. The semiconductor module 100 can be obtained by using of a combination of the semiconductor element 30A and a passive component. Furthermore, the semiconductor module 100 can also be obtained by using of a combination of the configuration shown in FIG. 13 and the passive component.

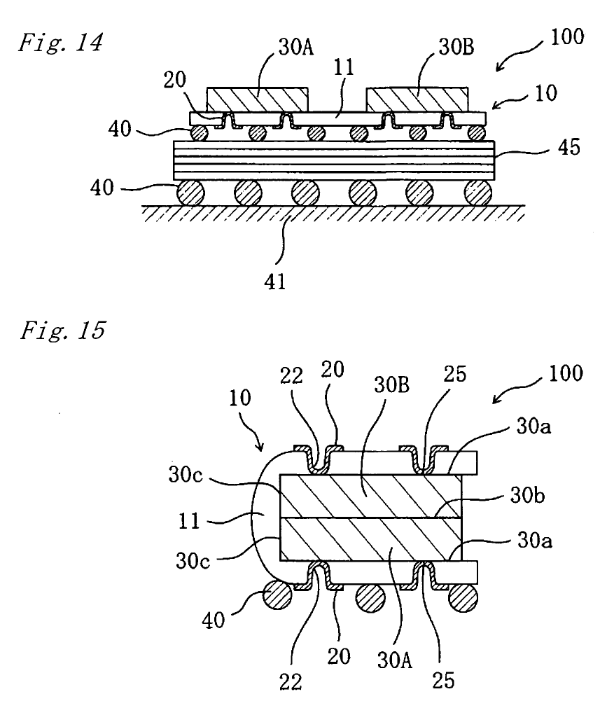

As shown in FIG. 14, the semiconductor module 100 shown in FIG. 13 can be mounted on the wiring board 41 via the commonly used interposers 45. In this case, the signal communication exchanged between the semiconductor elements 30A and 30B is performed via the wiring patterns 20 of the film interposer, which will lead to a higher speed processing. At least one of electrical communications except for the above can be performed via the interposer 45 and the wiring board 41. Incidentally, the fan-out is achieved by means of the film interposer 10, and thereby the cost reduction will be achieved by lowering the degree of the pith of the interposer 45.

The film interposer 10 can be used according to the embodiment as shown in FIG. 15. In this case, as shown in FIG. 15, the rear face 30b of the semiconductor element 30A is in contact with the rear face 30b of the semiconductor element 30B, in which case the semiconductor elements 30A and 30B are electrically interconnected via the film interposer 10. As shown, such film interposer 10 extends from the front face 30a of the semiconductor element 30A through around the side faces 30c of the semiconductor elements 30A and 30B up to the front face 30a of the semiconductor element 30B. That is to say, the film interposer 10 extends over the front face 30a of the semiconductor element 30A, and also extends over the side faces 30c of the semiconductor elements 30A and 30B, and moreover extends over the front face 30a of the semiconductor element 30B. As shown, at least a part 22 of the wiring pattern 20 of the film interposer 10 has been pressed toward the interior of the insulating resin layer 11 so that said part 22 is in contact with element electrode (not shown) formed on the front face 30a of said semiconductor element 30A, and also another at least a part 22 of the wiring pattern 20 of the film interposer 10 has been pressed toward the interior of the insulating resin layer 11 so that said part 22 is in contact with element electrode (not shown) formed on the front face 30a of said semiconductor element 30B.

Therefore, in other words, the semiconductor module 100 shown in FIG. 15 comprises:

a semiconductor element (corresponding to the combination of semiconductor elements 30A and 30B) having a principal face and a rear face which is opposite to the principal face, on each of which an element electrode is formed; and

a film member composed of an insulating resin layer having a front face and a rear face which is opposite to the front face, and a wiring pattern formed on the rear face of the insulating resin layer,

wherein the front face of the insulating resin layer of the film member is in contact with the principal face as well as the rear face of the semiconductor element so that the film member extends from the principal face of the semiconductor element through around a side face of the semiconductor element up to the rear face of the semiconductor element;

at least a part of the wiring pattern of said film member extends through said insulating layer so that said part is in contacted with the element electrode formed on the principal face of said semiconductor element; and

at least another part of the wiring pattern of said film extends through said insulating resin layer so that said at least another part of the wiring patter is in contact with the element electrode formed in the rear face of said semiconductor element.

The semiconductor module and the film interposer as shown in FIG. 15 have the same characteristics as those obtained by the production process of FIGS. 6(a) to (d). This is also true for the applied or modified examples. Therefore, the same characteristics will not be hereinafter described for the purpose of avoiding repetition in the description.

As described above with reference to FIG. 3, some film interposers 10 of the present invention are relatively easy to stack on each other. This means that a multilayer film interposer 10 can be obtained. In the multilayer film interposer 10, the wiring patterns 20 formed in respective films 11 are electrically interconnected by means of the interlaminar junctions 25.

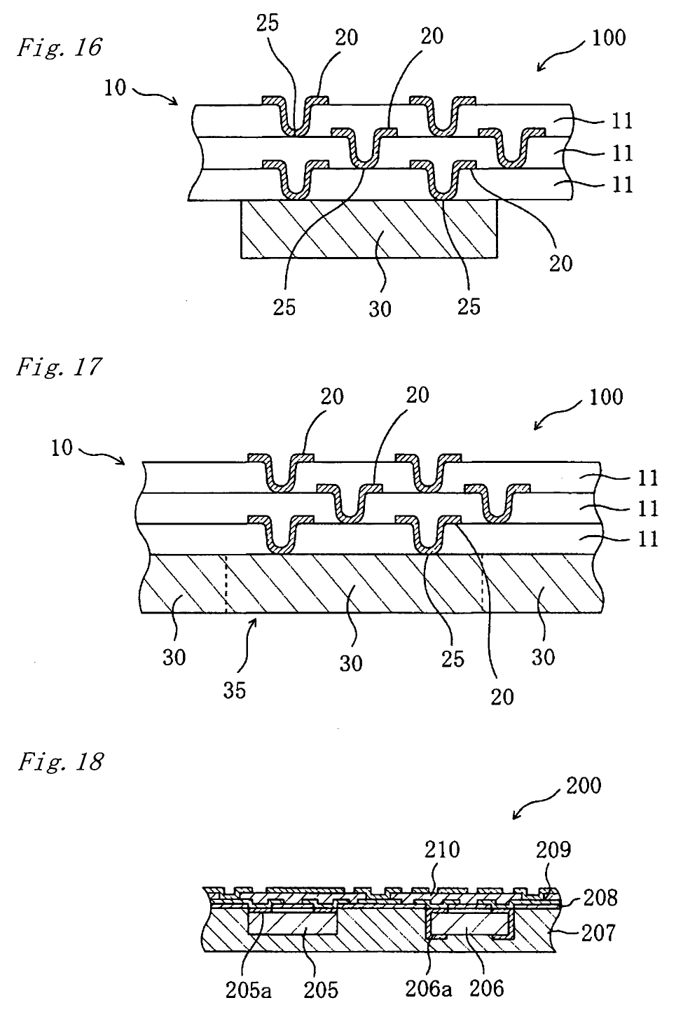

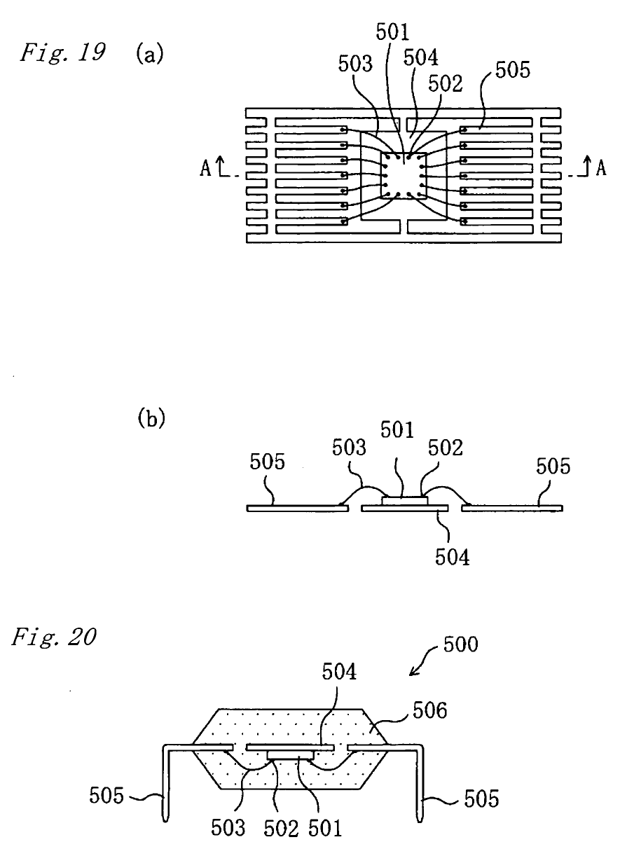

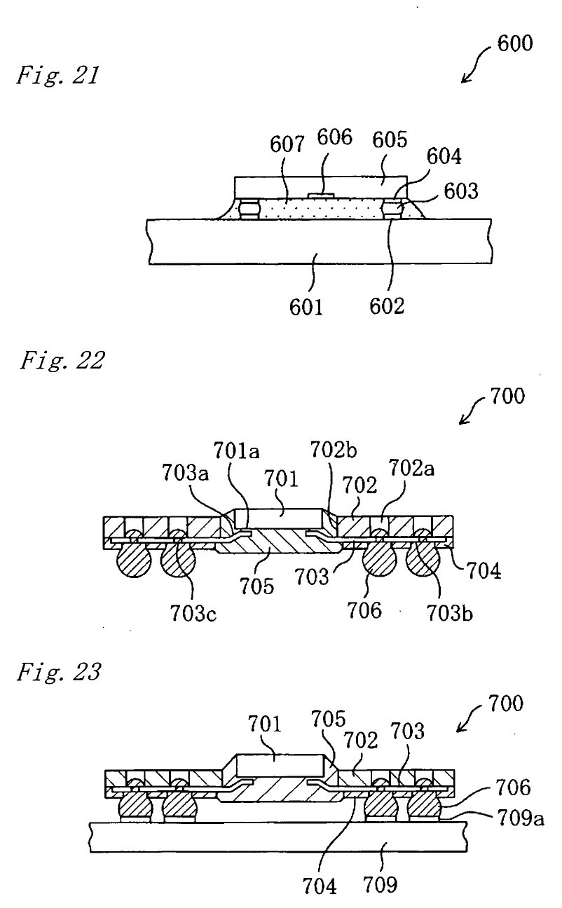

The film interposer 10 having the configuration shown in FIG. 16 is mounted or superposed on the semiconductor element 30, but not limited to that. Such film interposer 10 can be also mounted on a semiconductor wafer having a plurality of arranged semiconductor elements (barechips). In the case where the film interposer 10 is mounted on the semiconductor wafer before the barechip 30 is cut into smaller pieces, a waferlevel CSP (WL-CSP) can be obtained without difficulty, which will enhance the convenience in using the film interposer 10.

Although the present invention has been hereinabove described with reference to preferred embodiments, it will be understood by those skilled in the art that the present invention is not limited to such embodiments and can be modified in various ways.

As an additional remark, Japanese Patent Kokai Publication No. 4-283987 will be hereinafter described, although an electronic circuit device disclosed in this publication is fundamentally different from the present invention in terms of their technical meanings. The structure of such electronic device is shown in FIG. 18.

In the electronic circuit device 200 shown in FIG. 18, the external electrode terminal layers 205a, 206a of the circuit elements (e.g. semiconductor IC) 205, 206 buried in the insulating resin layer 207 are electrically interconnected by means of the wiring circuit conductive layer 209. The wiring circuit conductive layer 209 substantially corresponds to a copper wiring obtained by an electroless deposition process, and also is directly connected to the external electrode terminal layers 205a, 206a. Incidentally, reference numbers “208” and “210” indicate an adhesive layer and an interlaminar insulating resin respectively. This electronic circuit device 200 is obtained by means of the technique concerning so-called buildup layers. The publication does not disclose any technology related to the interlaminar junction of the semiconductor module as well as the film interposer of the present invention.

Furthermore, as another additional remark, Japanese Patent Kokai Publications Nos. 4-283987 and 49-27866 will be hereinafter described although technologies disclosed in these publications are fundamentally different from the present invention in terms of their technical meanings. They substantially relate to the technology wherein a part of the wiring pattern is crashed through the insulative layer and then connected to the metal substrate (e.g. aluminum substrate) for the purpose of ensuring an electrical connection between the wiring pattern and the metal substrate. In this technology, a screw tool is not used. By means of a connecting tool for connecting between a part of the wiring pattern and the metal substrate, the relatively soft surface of the aluminum substrate is deeply caved so that the surface of the substrate is deformed. Thus, in the case where this technology is carried out with respect to the element electrode the semiconductor element used in the present invention, the semiconductor element will be damaged. Incidentally, what are disclosed in those publications are alternative ways of the connection technique using the screw. It is a matter of course that they are not related to the fine-pitch connection technique such as the wire bonding, flip chip bonding and TAB techniques, and therefore they are fundamentally different from the present invention.

### INDUSTRIAL APPLICABILITY

The present invention provides the semiconductor module obtained by means of a novel fine-pitch connection technique, not the wire bonding, flip chip bonding and TAB techniques of the prior art. The present invention also provides the process for producing such semiconductor module.

In order to make full use of the characteristics of the semiconductor module of the present invention, such module can be mounted on a smaller and thinner electronic device whose mounting area is extremely limited. Thus, the semiconductor module of the present invention is used for various purposes. For example, the semiconductor module of the present invention is preferably used for a cellular phone. Furthermore, the semiconductor module of the present invention can be also used for a PDA, a notebook computer, a digital still camera, a thin-shaped television (i.e. FPD: flat-panel display) and the like.

In the case where a LED chip is used as the semiconductor element, the wiring pattern of the film interposer ensures an electrical continuity, which will lead to achievement of a luminescence device. That is to say, a semiconductor module or semiconductor device wherein light is emitted through the film can be obtained.

Furthermore, in the case where a LED chip is used as the semiconductor element, this will also lead to achievement of a luminescence device wherein two kinds of lights emitted from the LED chip and fluorescent material respectively are utilized. In the case where the semiconductor module of the present invention is used as a white light-emitting device, a blue LED chip serving to emit blue light is used as the semiconductor element, and also a yellow fluorescent material serving to emit yellow light is used as a fluorescent material serving to distribute light over the film. In this case, a gallium nitride (GaN)-based material may be appropriately used as the LED chip, and YAG-based fluorescent material and the like may be appropriately used as the fluorescent material. It will be noted that not only the blue LED chip but also an ultraviolet LED chip serving to emit ultraviolet light can be also used. In this case, the white light-emitting device can be obtained wherein the fluorescent material serving to emit red light (R), green light (G) and blue light (B) due to the excitation by means of light emitted from the ultraviolet LED chip is distributed over the film. It is a matter of course that a desired light-emitting device can be also obtained by selecting the LED chip and the fluorescent material appropriately.

What is claimed is:

1. A semiconductor module, comprising:
a semiconductor element having a principal face on which an element electrode is formed; and
a film member comprising an insulating resin layer having a front face and a rear face which is opposite to said front face, and a wiring pattern formed on the rear face of said layer,
wherein said semiconductor element is superposed on said film member so that the principal face of said semiconductor element is in contact with the front face of the insulating resin layer of said film member; and
a part of the wiring pattern of said film member extends through said insulating resin layer, so that said part is in contact with the element electrode of said semiconductor element.

2. The semiconductor module according to claim 1, wherein said insulating resin layer is made of a transparent resin.

3. The semiconductor module according to claim 1, wherein said insulating resin layer is made of a polyimide or an aramid.

4. The semiconductor module according to claim 1, wherein said insulating resin layer is a coating film obtained by applying an insulating resin over the principal face of said semiconductor element.

5. The semiconductor module according to claim 1, wherein said semiconductor element is a semiconductor bare chip or a chip size package.

6. The semiconductor module according to claim 1, wherein said wiring pattern is embedded in said insulating resin layer on the rear face of said layer.

7. The semiconductor module according to claim 1, wherein said part of the wiring pattern, which extends through said insulating resin layer, is obtained by pressing a part of the wiring pattern into said insulating resin layer.

8. The semiconductor module according to claim 1, wherein a cross-section of said part of said wiring pattern is generally “U” in shape.

9. The semiconductor module according to claim 1, wherein a junction obtained due to being in contact between said part of the wiring pattern and the element electrode serves to electrically interconnect the wiring pattern and the element electrode.

10. The semiconductor module according to claim 1, wherein a junction obtained due to being in contact between said part of the wiring pattern and the element electrode has been treated by means of an ultrasonic wave.

11. The semiconductor module according to claim 10, wherein said junction comprises an alloy consisting of plural metals.

12. The semiconductor module according to claim 11, said plural metals are selected from the group consisting of a copper an aluminum, a gold, a silver, a platinum and a vanadium.

13. The semiconductor module according to claim 1, further comprising one or more another semiconductor element(s) having a principal face on which an element electrode is formed,
wherein said another semiconductor element(s) is superposed on said film member so that the principal face of said another semiconductor element(s) is in contact with the front face of the insulating resin layer of said film member; and
at least another part of the wiring pattern of said film member extends through said insulating resin layer, so that said at least another part is in contact with said electrode of said another semiconductor element(s).

14. The semiconductor module according to claim 1, wherein a front face of said film member and a rear face of said film member which face is opposite to said front face are approximately the same as the principal face of said semiconductor element in size.

15. The semiconductor module according to claim 1, wherein a front face of said film member and a rear face of said film member which face is opposite to said front face are larger than the principal face of said semiconductor element in size.

16. The semiconductor module according to claim 1, wherein a solder ball is formed on a rear face of said film member.

17. The semiconductor module according to claim 1, further comprising an interposer that is electrically connected to a wiring board, wherein p1 said film member is electrically connected to said interposer.

18. The semiconductor module according to claim 1, wherein another film member is superposed on said film member so that they are laminated to each other.

19. The semiconductor module according to claim 18, wherein said semiconductor element is a semiconductor wafer.

20. A semiconductor module, comprising:
a semiconductor element having a principal face on which an element electrode is formed and a rear face of said semiconductor element which face is opposite to said principal face;
a film member comprising an insulating resin layer having a front face and a rear face which is opposite to said front face, and a wiring pattern formed on the rear face of said insulating resin layer; and
a wiring board,
wherein said semiconductor element is mounted on said wiring board so that the rear face of said semiconductor element is in contact with said wiring board;
a front face of said film member and a rear face of said film member which face is opposite to said front face are larger than the principal face of said semiconductor element in size, and also said film member is mounted over said semiconductor element so that the principal face of said semiconductor element is in contact with the front face of said insulating resin layer of said film member, said film member extending up to said wiring board around the semiconductor element; and
at least a part of the wiring pattern of said film member extends through said insulating resin layer so that said part of the wiring pattern is in contact with the element electrode of said semiconductor element, whereas at least a part of the wiring pattern other than said part of the wiring pattern extends through said insulating resin layer so that said at least a part of the wiring pattern other than said part of the wiring pattern is in contact with an electrode formed on said wiring board.

21. The semiconductor module according to claim 20, wherein said insulating resin layer is made of a transparent resin.

22. The semiconductor module according to claim 20, wherein said insulating resin layer is made of a polyimide or an aramid.

23. The semiconductor module according to claim 20, wherein said semiconductor element is a semiconductor bare chip or a chip size package.

24. A semiconductor module, comprising:
a semiconductor element having a principal face and a rear face which is opposite to said principal face, on each of which an element electrode is formed; and
a film member comprising an insulating resin layer having a front face and a rear face which is opposite to said front face, and a wiring pattern formed on the rear face of said insulating resin layer,
wherein the front face of the insulating resin layer of said film member is in contact with the principal face as well as the rear face of said semiconductor element so that said film member extends from the principal face of said semiconductor element through around a side face of said semiconductor element up to the rear face of said semiconductor element;
at least a part of the wiring pattern of said film member extends through said insulating layer so that said part is in contacted, with the element electrode formed on the principal face of said semiconductor element; and
at least another part of the wiring pattern of said film extends through said insulating resin layer so that said at least another part of the wiring patter is in contact with the element electrode formed in the rear face of said semiconductor element.

25. The semiconductor module according to claim 24, wherein said insulating resin layer is made of a transparent resin.

26. The semiconductor module according to claim 24, wherein said insulating resin layer is made of a polyimide or an aramid.

27. The semiconductor module according to claim 24, wherein said semiconductor element is composed of a plurality of semiconductor elements.

28. A film interposer, comprising an insulating resin layer having a front face and a rear face which is opposite to said front face, and a wiring pattern formed on one face of said insulating resin layer,
wherein a part of said wiring pattern extends through said insulating resin layer so that said part is exposed on the other face of said insulating resin layer.

29. The film interposer according to claim 28, wherein said wiring pattern is embedded in said insulating resin layer on said one face of said layer.

30. The film interposer according to claim 28, wherein a cross-section of said part of said wiring pattern is generally “U” in shape.

31. A process for producing a semiconductor module, said process comprising the steps of:
(a) preparing a semiconductor element having a principal face on which an element electrode is formed;
(b) preparing a film member comprising an insulating resin layer having a front face and a rear face which is opposite to said front face, and a wiring pattern formed on the rear face of said insulating resin layer;
(c) superposing said semiconductor element on said film member so that the principal face of said semiconductor element is in contact with the front face of the insulating resin layer of said film member; and
(d) pressing a part of the wiring pattern into said film member so that said part is in contact with the element electrode of said semiconductor element.

32. The process for producing a semiconductor module according to claim 31, wherein
said film member is transparent so that said step (d) is visually carried out, in which case an alignment between said part of the wiring pattern and the electrode of said semiconductor element is visually performed through the transparent film member.

33. The process for producing a semiconductor module according to claim 31, wherein an ultrasonic wave is applied to a junction obtained due to being in contact between said part of the wiring pattern and the element electrode.

34. The process for producing a semiconductor module according to claim 33, a physical characteristic of said part of the wiring pattern is measured during the application of said ultrasonic wave.

35. The process for producing a semiconductor module according to claim 34, said measured physical characteristic is a resistance of said wiring pattern.
